(19) United States
(12) Patent Application Publication
(10) Pub. No.: US 2014/0284759 A1
(43) Pub. Date: Sep. 25, 2014

(54) SEMICONDUCTOR DEVICE AND METHOD OF MANUFACTURING THE SAME

(71) Applicant: KABUSHIKI KAISHA TOSHIBA, Minato-ku (JP)

(72) Inventors: Kaori Fuse, Kanagawa-ken (JP); Akira Komatsu, Kanagawa-ken (JP)

(73) Assignee: KABUSHIKI KAISHA TOSHIBA, Minato-ku (JP)

(21) Appl. No.: 14/019,127

(22) Filed: Sep. 5, 2013

(30) Foreign Application Priority Data
Mar. 22, 2013 (JP) 2013-061105

(51) Int. Cl. H01L 21/02; H01L 29/06; H01L 21/762

(52) U.S. Cl. CPC H01L 21/02255; H01L 21/76224; H01L 29/0649
USPC 257/506; 438/424

(57) ABSTRACT

An aspect of the present embodiment, there is provided a method of manufacturing a semiconductor device, the method includes providing trenches in an end terminal area of a substrate, the end terminal area surrounding an element area of the a substrate, the trenches surrounding the element area, filling a fluent material mixed with carbonate, oxide and solvent in the each of the trenches, burning the fluent material in the trench to embed an insulator in the trench, and providing an element unit in the element area.

### CROSS REFERENCE TO RELATED APPLICATION

This application is based upon and claims the benefit of priority from prior Japanese Patent Application No. 2013-061105, filed on Mar. 22, 2013, the entire contents of which are incorporated herein by reference.

### FIELD

Exemplary embodiments described herein generally relate to a method of manufacturing a semiconductor device and the semiconductor device.

### BACKGROUND

An element area in which a semiconductor element is provided, and an end terminal area in which the semiconductor element are surrounded, are provided in semiconductor devices such as a power metal-oxide-semiconductor field effect transistor (MOSFET), a power insulated gate bipolar transistor (IGBT) or the like.

Trenches are provided in the end terminal area and poly crystalline silicon and a complex layer which has a stacked layer with a silicon oxide and aluminum oxide, for example, is embedded.

In such a case, leakage current can be controlled, however, productivity may be degraded, when the complex layer having the stacked layer, silicon oxide and aluminum oxide, for example, is embedded.

### BRIEF DESCRIPTION OF THE DRAWINGS

FIG. 1 is a plane view showing a semiconductor device according to a first embodiment;

FIG. 2 is a cross-sectional view showing the semiconductor device according to the first embodiment;

FIG. 3 is a cross-sectional view showing the semiconductor device according to the first embodiment;

FIGS. 4A-4D are cross-sectional views showing a method of manufacturing a semiconductor device according to a second embodiment;

FIG. 5 is a cross-sectional view showing the method of manufacturing the semiconductor device according to the second embodiment;

FIGS. 6A-4C are cross-sectional views showing the method of manufacturing the semiconductor device according to the second embodiment;

FIGS. 7A-7C are cross-sectional views showing the method of manufacturing the semiconductor device according to the second embodiment;

FIGS. 8A-8B are cross-sectional views showing the method of manufacturing the semiconductor device according to the second embodiment;

FIGS. 9A-9B are cross-sectional views showing the method of manufacturing the semiconductor device according to the second embodiment;

### DETAILED DESCRIPTION

An aspect of the present embodiment, there is provided a method of manufacturing a semiconductor device, the method includes providing trenches in an end terminal area of a substrate, the end terminal area surrounding an element area of the a substrate, the trenches surrounding the element area, filling a fluent material mixed with carbonate, oxide and solvent in the each of the trenches, burning the fluent material in the trench to embed an insulator in the trench, and providing an element unit in the element area.

An aspect of another embodiment, there is provided a method of manufacturing a semiconductor device, the method includes providing trenches in an end terminal area of a substrate, the end terminal area surrounding an element area of the substrate, the trenches surrounding the element area, filling a fluent material mixed with a powder raw material which includes carbonate and oxide, and solvent in the each of the trenches, burning the fluent material in the trench to embed an insulator in the trench, and providing an element unit in the element area.

An aspect of another embodiment, there is provided a semiconductor device, which includes an element area which includes an element unit on a substrate, an end terminal provided at a periphery of the element area, trenches included in the end terminal area, the trenches surrounding the element area, and an insulator including barium titanate, the insulator being embedded in each of the trenches.

Embodiments will be described below in detail with reference to the attached drawings mentioned above. As drawings are schematic and conceptual, a relation between a thickness and a length of each portion or a ratio between portions is not necessary to identify with the corresponding real value. Further, it is not restricted to represent same size or ratio in a case of pointing out the same portion in the drawings, accordingly, the same size or ratio is differently represented in the drawings.

Further, allows X, Y, Z in the drawings are indicated three directions which are orthogonal each other. The allows X, Y are represented in parallel direction to a substrate 2, and the allow Z is represented in perpendicular to the substrate 2. Throughout the attached drawings, similar or same reference numerals show similar, equivalent or same components, and the description is not repeated.

In the description mentioned below, explanation is performed in a case that a semiconductor device 1 according to the first embodiment is a vertical-type power MOSFET. On the other hand, the semiconductor device 1 according to the first embodiment is not restricted to the vertical-type power MOSFET. The semiconductor device 1 according to the embodiment may be a horizontal-type power MOSFET, a vertical-type power IGBT, a horizontal-type power IGBT or the like.

### First Embodiment

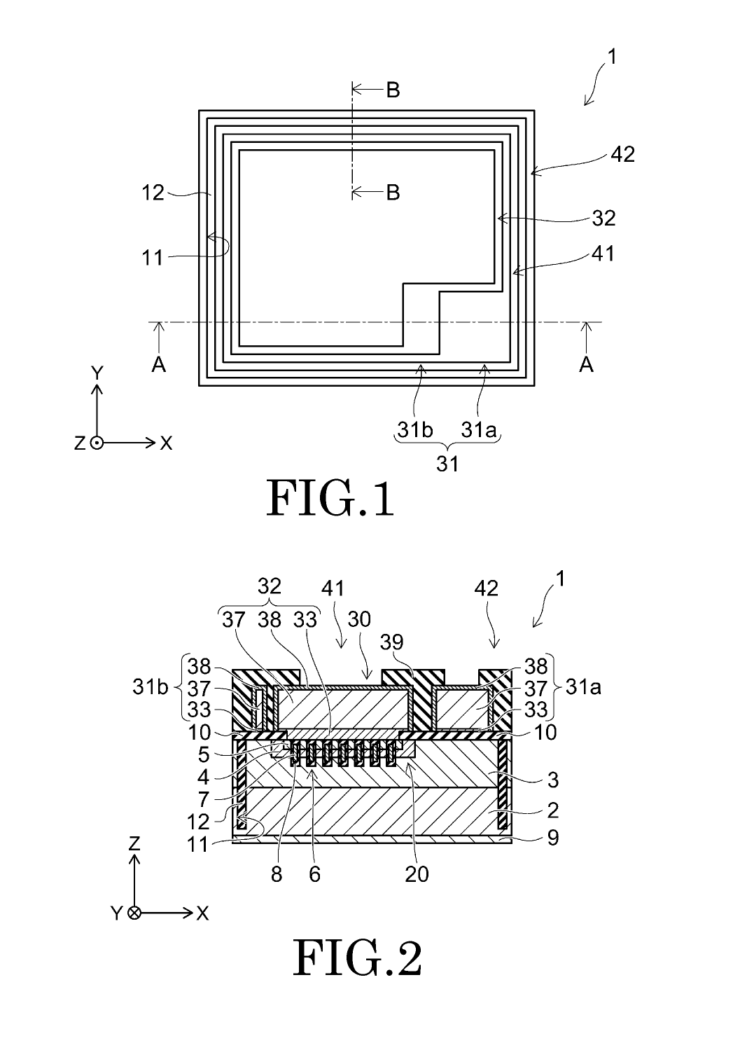

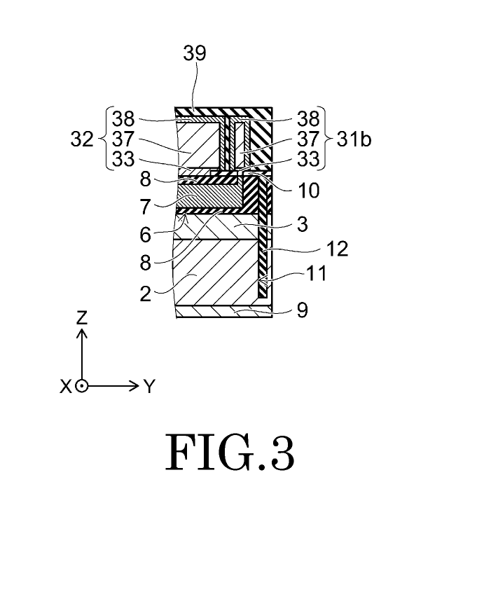

FIGS. 1-3 are schematic views showing a semiconductor device 1 according to a first embodiment. FIG. 1 is a plane view showing a semiconductor device according to the first embodiment. An insulator 10 and an insulating layer 39 are omitted for convenience. FIG. 2 is a cross-sectional view of A-A cross-section in FIG. 1. FIG. 3 is a cross-sectional view of B-B cross-section in FIG. 1.

As shown in FIGS. 1-3 an element area 41 and an end terminal area 42 are provided. The element area 41 is provided in a central portion of the substrate 2, and the end terminal area 42 is provided to surround a periphery of the element area 41.

An element unit 20 and electrode unit 30 are provided in the element area 41. The element unit 20 includes a substrate 2, an epitaxial layer 3, a base area 4, a source area 5, a trench 6, trench gate 7, a gate insulator 8, a drain electrode 9 and an insulator 10. The substrate 2 is composed of an n+ type semiconductor, for example.

The epitaxial layer 3 is provided on one surface of the substrate 2. The epitaxial layer 3 is composed of an n− type semiconductor, for example. The base area 4 is provided on a surface area of the epitaxial layer 3. The base area 4 is composed of a p-type semiconductor, for example. The source area 5 is provided on a surface area of the base area 4. The source area 5 is composed of an n+ type semiconductor. The trench 6 penetrates through the base area 4 and the source area 5 to reach the epitaxial layer 3. The trench 6 is opened on a surface of the source area 5 to extend in the Y direction. The trenches 6 are provided in a prescribed interval.

Each of the trench gates 7 is provided inside of each of the trenches 6. As shown in FIG. 3, the trench gate 7 is extended in the Y direction to penetrate through the gate insulator 8 and the insulator 10, so that the trench gate 7 is connected to a connection unit 31b of a gate electrode 31. The trench gate 7 is composed of poly crystalline silicon doped with impurities, for example. In addition, numbers of the trench 6, the trench gate 7 or the like can be suitably changed.

Each of the gate insulators 8 is provided inside of each of the trenches 6. The gate insulator 8 is provided to cover the trench gate 7 in the trench 6. The drain electrode 9 is provided on the opposed side to the side where the epitaxial layer 3 is provided on the surface of the substrate 2. The drain electrode 9 is composed of aluminum (Al), for example. The insulator 10 is provided on the epitaxial layer 3. The insulator 10 includes an opening. The insulator 10 may be mono layer or a stacked layer with layers.

The electrode unit 30 includes the gate electrode 31 and the source electrode 32. The gate electrode 31 and the source electrode 32 are covered with the insulating layer 39. The gate electrode 31 is provided on the insulator 10. The gate electrode 31 includes a main body unit 31a and a connection unit 31b surrounding a periphery of a source electrode 32. The trench gate 7 penetrates into the gate insulator 8 and the insulator 10 to connect to the connection unit 31b as reference to FIG. 3. The main body unit 31a is used as a gate pad and the connection unit 31b is used as a gate leading wiring. The source electrode 32 is provided inside of an opening in which source area 5 provided on the insulator 10 is exposed. In addition, the source electrode 32 is used as a source pad.

The main body unit 31a and the connection unit 31b of the gate electrode 31, and the source electrode 32 include a barrier layer 33, a metal layer 37 and a metal layer 38.

The metal layer 37 provided in the connection unit 31b of the gate electrode 31 is connected to the trench gate 7 via the barrier layer 33 The metal layer 37 provided in the source electrode 32 is provided inside of the opening in the insulator 10. The metal layer 37 provided in the opening is connected to the source area 5 via the barrier layer 33.

The barrier layer 33 is composed of titanium (Ti), titanium-tungsten (TiW), titanium nitride (TiN) or the like. A thickness of the barrier layer 33 can be set to be nearly 300-500 nm. The barrier layer 33 is provided to prevent elements in the metal layer 37 from diffusing into an inner region of the element unit 20.

The metal layer 37 can be composed of a conductive material, cupper (Cu) or the like. A thickness of the metal layer 37 can be set to be nearly 5-10 μm. The metal layer 38 is provided to cover exposed surfaces, an upper surface and a side surface, of the metal layer 37.

The metal layer 38 can be selected at least one element from a group of gold (Au), platinum (Pt), palladium (Pd) or the like, for example.

A thickness of the metal layer 38 can be set to be nearly 0.05 μm. An underlying layer composed of Ni/Pd, nickel (Ni), tin (Sn) or the like can be provided between the metal layer 38 and the metal layer 37 to have a thickness of 1-2 μm.

The insulating layer 39 is provided to cover the surface of the metal layer 38. Openings are provided in the insulating layer 39. The metal layer 38 provided on the upper surface of the metal layer 37 is exposed in the opening. The insulating layer 39 can be composed of polyimide (PI), permanent resist, plasma-SiN, Plasma SiO or the like. The insulating layer 39 may be a single layer or a stacked layer with layers

A thickness of the insulating layer 39 can be set to be nearly 1-20 μm. The insulating layer 39 is provided to protect the gate electrode 31 and the source electrode 32. The insulating layer 39 can be provided, if necessary.

The trench 11 and the insulator 12 are provided in the end terminal area 42. The trench 11 is provided to surround a periphery of the element area 41. The trench 11 penetrates the epitaxial layer 3 to reach the substrate. The trench 11 is opened in the surface of the epitaxial layer 3. A width of the trench 11 (X direction or Y direction) is set to not less than 30 μm and-not more than 100 μm. A depth (Z direction) of the trench 11 can be set to be nearly more than 50 μm.

The insulator 12 is embedded in the trench 11. The insulator 12 includes barium titanate (BaTiO₃).

### Second Embodiment

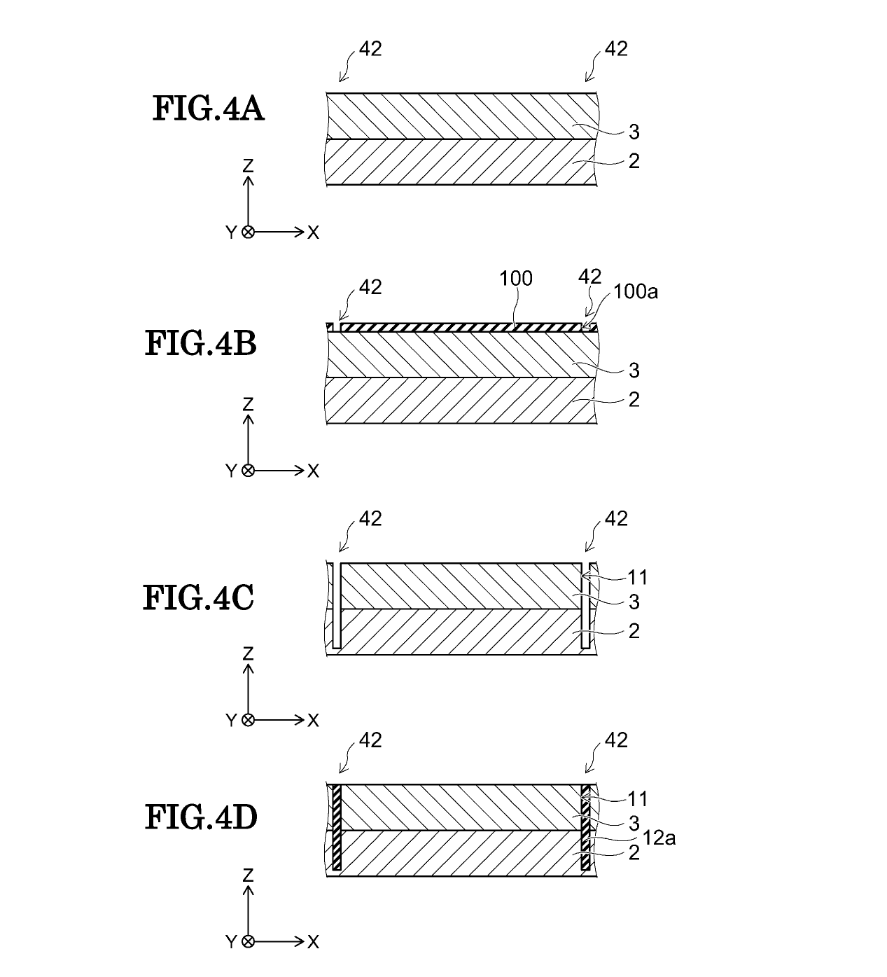

FIGS. 4A-9B are schematically cross-sectional views showing a method of manufacturing a semiconductor device 1 according to a second embodiment. A plurality of the semiconductor devices 1 are integrally provided in the method of manufacturing a semiconductor device 1 according to a second embodiment, subsequently, each of the semiconductor devices 1 is separated. Here, a region in which one semiconductor device 1 is provided is described for convenience. The same steps can be applied when one semiconductor device 1 is manufactured.

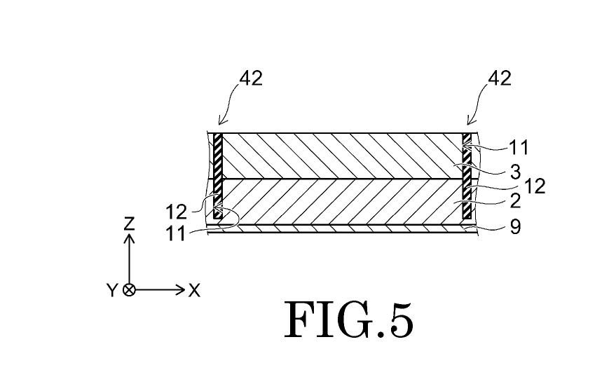

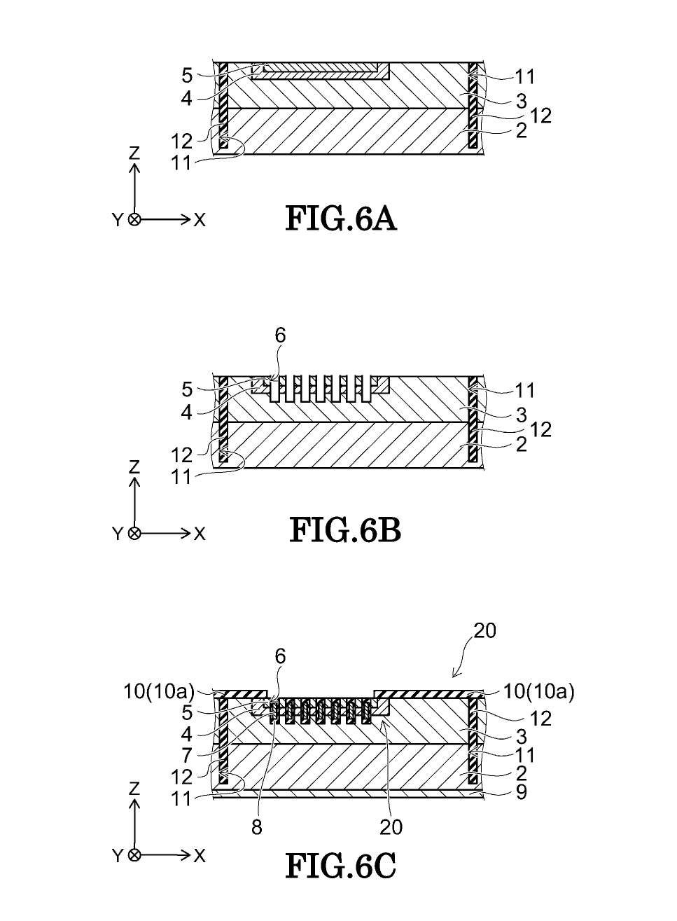

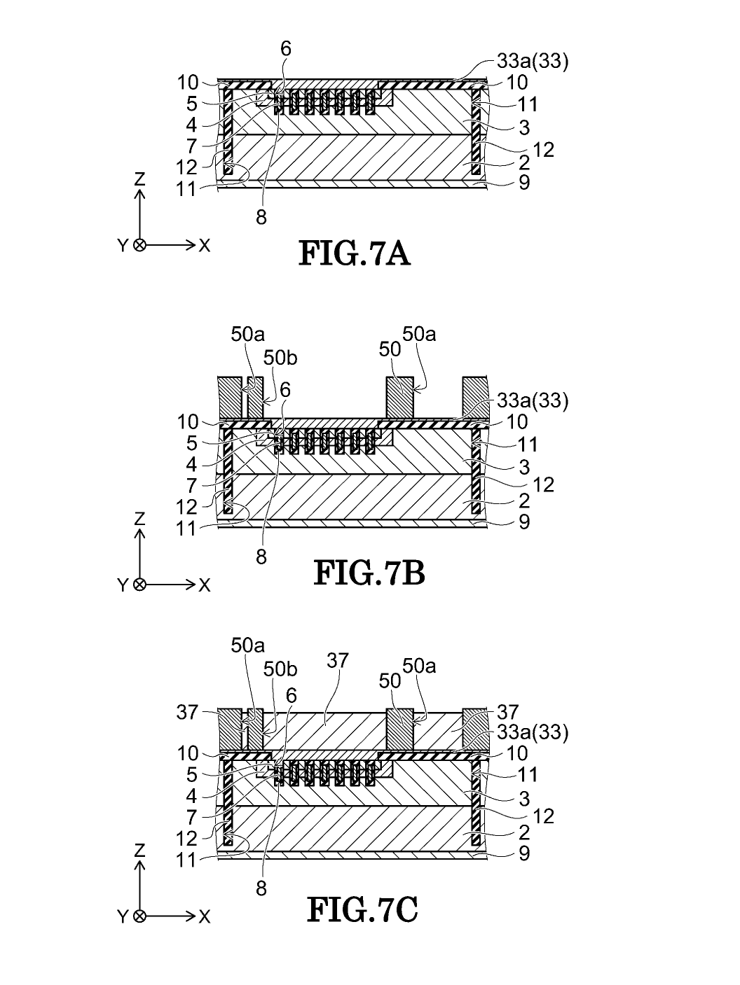

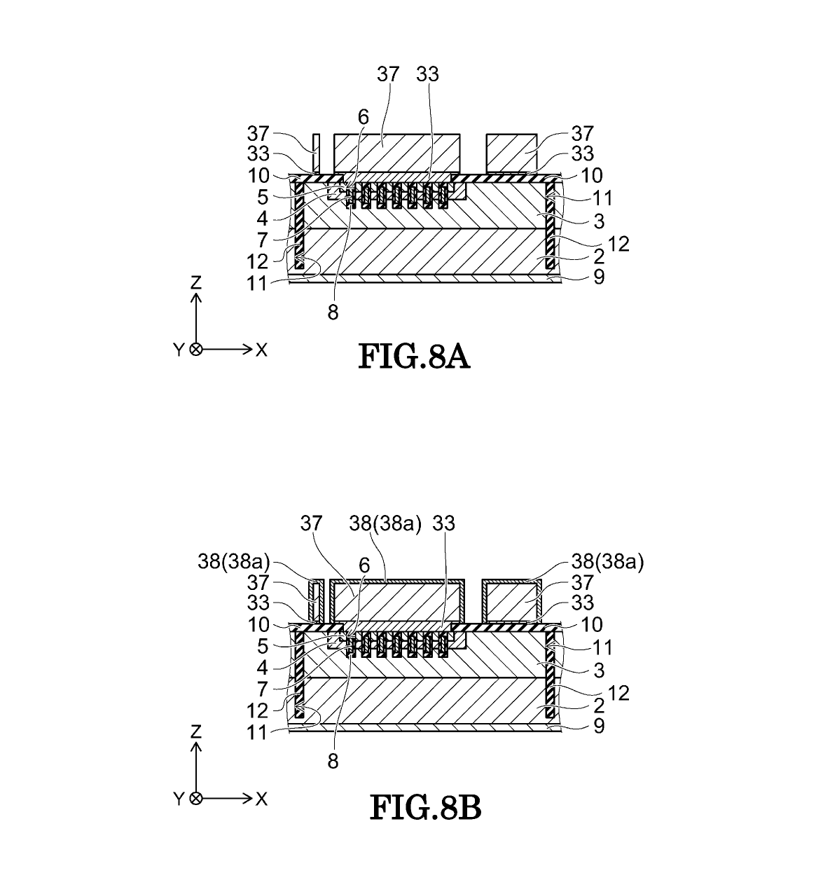

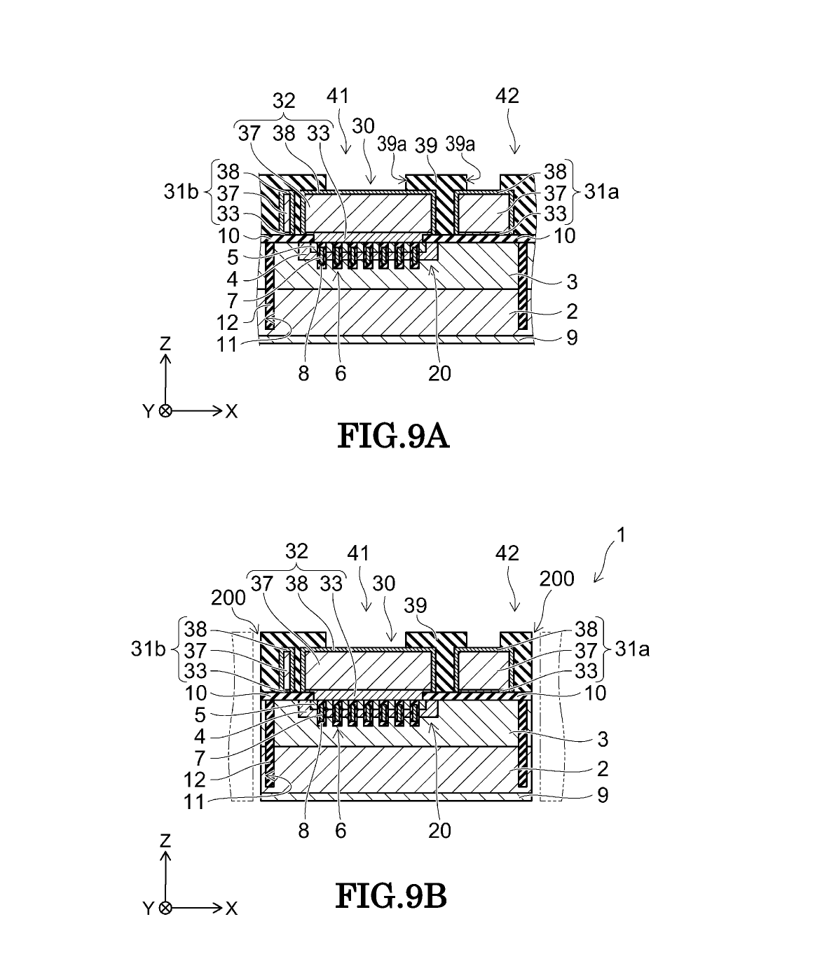

FIGS. 4A-9B are cross-sectional views of A-A cross-section in FIG. 1. FIG. 5 is the schematically cross-sectional view which is continuing from FIG. 4D. FIG. 6A is the schematically cross-sectional view which is continuing from FIG. 5. FIG. 7A is the schematically cross-sectional view which is continuing from FIG. 6C. FIG. 8A is the schematically cross-sectional view which is continuing from FIG. 7C. FIG. 9A is the schematically cross-sectional view which is continuing from FIG. 8B. FIGS. 4A-5 are the schematically cross-sectional views showing formation of a trench 11 and an insulator 12 in an end terminal area 42. FIGS. 6A-6C are the schematically cross-sectional views showing formation of an element unit 20. FIGS. 7A-9A are the schematically cross-sectional views showing formation of an electrode unit 30. FIG. 9B is the schematically cross-sectional view showing an aspect of separating into each of the semiconductor devices 1.

First, a trench 11 and an insulator 12 is formed in the end terminal area 42. As shown in FIG. 4A, an n− type semiconductor is epitaxially grown on a substrate 2 formed as an n+ type semiconductor to form an epitaxial layer 3. As shown in FIG. 4B, a mask pattern 100 including a desired opening 100a is formed on the epitaxial layer 3. A resist mask can be used as the mask pattern 100, for example. The mask pattern 100 can be formed by .photolithography.

As shown in FIG. 4C, the epitaxial layer 3 and the substrate 2 are etched via the opening 100 of the mask pattern 100 so as to form the trench 11. The trench 11 penetrates through the epitaxial layer 3 to reach the substrate 2. The trench 11 is opened at the surface of the epitaxial layer 3. A width, which is an X direction or a Y direction, of the trench 11 can be set to be not less than 30 μm and not more than 100 μm. A depth, which is the Z direction, of the trench 11 can be set to be more than 50 μm. Etching of the epitaxial layer 3 and the substrate 2 can be performed by reactive ion etching (RIE), for example. Successively, mask pattern 100 is removed. Removing the mask pattern 100 can be performed by dry ashing or wet ashing, for example.

An insulator 12 is embedded into the trench 11. The insulator 12 including ceramics is embedded into the trench 11 by using solid phase technique, which is also called solid phase reaction technique or ceramics technique. Here, a fluent material included powder raw material, in which carbonate and oxide is contained, and solvent are filled in the trench 11 to form the insulator 12 by burning according to findings obtained by Applicants. As a result, productivity can be remarkably improved. Barium carbonate and titanium dioxide are used as the carbonate and the oxide, respectively, so that the insulator 12 having barium titanate can be formed by burning, for example.

As shown in FIG. 4D, the fluent material 12a to be transformed to the insulator 12 is filled in the trench 11. The fluent material 12a to be transformed to the insulator 12 can be formed by mixing barium carbonate, titanium dioxide and solvent such as water, alcohol or the like. Filling the fluent material 12a to be transformed to the insulator 12 can be dispensing technique, for example. However, the method is not restricted to dispensing technique. The fluent material 12a can be filled by using spin coat technique or the like, for example.

As shown in FIG. 5, the fluent material 12a is burned to form barium titanate such that the insulator 12 which includes barium titanate, is embedded in the trench 11. In such a manner, burning the fluent material 12a including barium carbonate and titanium dioxide causes a reaction described below to produce insulator 12 with barium titanate.

BaCO₃+TiO₂→BaTiO₃+CO₂

A temperature of burning can be set to be not less than 900° C. and not more than 1,200° C. Successively, residual barium titanate on the surface of the epitaxial layer 3 is removed. The residual barium titanate can be removed by using chemical mechanical polishing (CMP) or the like, for example.

An element unit 20 and an electrode unit 30 are formed in the element area 41. As shown in FIG. 6A, a base area 4 and a source area 5 are formed. A mask pattern having a desired opening is formed on the epitaxial layer 3. Successively, p-type impurities are implanted into the epitaxial layer 3 via the opening of the mask pattern to be thermally diffused so that the base area 4 composed of p-type semiconductor is formed. Successively, a mask pattern having a desired opening is formed on the base area 4. N-type impurities are implanted into the base area 4 via the opening of the mask pattern to be thermally diffused so that the source area 5 composed of n+ type semiconductor is formed.

As shown in FIG. 6B, a mask pattern having a desired opening is formed on the epitaxial layer 3, the base area 4 and the source area 5 to form a trench 6 by using RIE or the like. The trench 6 penetrates through the base area 4 and the source area 5 to reach the epitaxial layer 3. The trench 6 is opened on a surface of the source area 5 to extend in a Y direction.

As shown in FIG. 6C, a gate insulator 8 is formed on an inside wall of the trench 6 doped with impurities, further, a poly crystalline silicon is embedded inside of the gate insulator 8. The poly crystalline silicon, which is exposed on an area source where the electrode 32 is formed, is etched back to form the trench gate 7. Successively, an insulating material is embedded in a portion where the poly crystalline silicon is etched back so as to form a gate insulating film 8. A film 10a to be an insulator 10 is formed on the epitaxial layer 3, the base area 4, the source area 5 and the insulating film 8. The insulating film can be selected from silicon dioxide (SiO₂), silicon nitride (SiN) or the like, for example. A thickness of the insulator 10 can be set to be nearly 500-1,000 nm, for example. Subsequently, a mask pattern having desired openings is formed on the film 10a. The openings is formed in an area to be formed of a connection unit of gate electrode 31 and an area formed of a source electrode 32 by using RIE or the like to form the insulator 10 having the opening.

A drain electrode 9 composed of a metal, aluminum or the like, is formed at the opposed side to the side at which the epitaxial layer 3 is formed on the substrate 2. Forming the drain electrode 9 can be carried out after forming the insulator 10 or before forming the epitaxial layer 3. As described above, the element unit 20 can be provided.

Materials, sizes, shape or the like, and forming, etching and thermally diffusing techniques or the like of the substrate 2, the epitaxial layer 3, the base area 4, the source area 5, the trench 6, the trench gate 7, the gate insulator 8, the drain electrode 9 and the insulator 10 can be applied by conventional techniques. Further, a number of the trench gates 7 or the like can be suitably changed.

Processing steps of forming an electrode unit 30 are demonstrated below. As shown in FIG. 7A, a film 33a to be a barrier layer 33 is formed on the insulator 10. The film 33a can be formed by using sputtering technique. As a material of the film 33a, Ti, TiW, TiN or the like can be used. A thickness of the film 33a can be set to 300-500 nm, for example.

As shown in FIG. 7B, a mask 50 is formed on the film 33a. When the mask 50 is formed, openings 50a, 50b are formed by photolithography, for example. The openings 50a are formed at an area where a main body unit 31a and a connection unit 31b of the gate electrode 31 are formed. The openings 50b are formed at an area where the source electrode 32 is formed. A photo resist can be used as a material of the mask 50, for example. A thickness of the mask 50 can be set to be a value larger than a thickness of the metal layer 37, for example, nearly 5-10 μm.

As shown in FIG. 7C, the metal layer 37 is formed in the openings 50a, 50b of the mask 50. The metal layer 37 can be formed by plating. When the metal layer 37 is formed by using electro-plating, a seed layer composed of copper or the like, for example. On the other hand, when the metal layer 37 is formed by using non-electro-plating, a seed layer is not necessary. Successively, the mask is removed. The mask can be removed by dry ashing, wet ashing or the like, for example.

As shown in FIG. 8A, the film 33a is etched using the metal layer 37 as a mask to form the barrier layer 33. The film 33a can be removed by wet etching using alkali etchant, for example. Dry etching such as RIE or the like can also remove the film 33a.

As shown in FIG. 8B, a film 38a to be a metal layer 38 is formed to cover an exposed surface of a stacked body constituted with the barrier layer 33 the metal layer 37. An approach described below can be applied when the film 38a is formed. An underlying layer is formed to cover the exposed surface of a stacked body, and the film 38a is subsequently formed on the underlying layer.

The underlying layer composed of Ni/Pd, Ni, Sn or the like, for example, is formed, and the film 38a composed of Au, Pd, Pt or the like is formed on the underlying layer. A thickness of the underlying layer can be set to be nearly 1-2 μm and a thickness of the film 38 can be set to be nearly 0.05 μm. The underlying layer and the film 38 can be by using non-electro-plating. The underlying layer and the film 38 other than the exposed surface of the stacked body are removed to form the metal layer 38. The underlying layer and the film 38 other than the exposed surface of the stacked body are removed by using wet etching or dry etching, for example.

As shown in FIG. 9A, an insulating layer 39 is formed to cover a surface of the metal layer 38. When the insulating layer 39 is formed to cover the surface of the metal layer 38, an opening 39a is formed to expose the metal layer 38 provided on an upper surface the metal layer 37. The insulating layer 39 can be composed of polyimide, permanent resist, plasma-SiN plasma-SiO or the like. The insulating layer 39 can be constituted with single film or a complex film, for example. The insulating layer 39 can be formed by printing, photolithography or the like. A thickness of the insulating layer 39 can be set to be nearly 1-20 μm. The insulating layer 39 to protect the gate electrode 31 and the source electrode 32 can be formed in a case of necessity. As described above, the electrode unit 30 can be provided.

As shown in FIG. 9B, the substrate 2 is cut along a dicing line to be separate into the each of chips so that each of semiconductor devices 1 is produced. The substrate 2 is cut along a dicing line 200 by a dicing saw to be separated into each of the semiconductor devices 1. When each semiconductor device 1 is manufactured one by one, the separating step is not necessary. The semiconductor device 1 which includes the insulator 12 embedded in the substrate to surround the element area 41 can be manufactured as described above.

The insulator 12 having barium titanate has highly thermal resistance. Accordingly, after the insulator 12 is embedded in the trench 11, the element unit 20 and the electrode unit 30 can be provided in the element area 41. In other words, heating is performed in thermal diffusion process, for example, when the element unit 20 is formed. However, the barium titanate has highly thermal resistance, generation of degradation or damage in the element unit 20 can be prevented. Furthermore, processing steps described below can be applied. The fluent material 12a mixed with a powder raw material, for example barium carbonate, titanium dioxide or the like, and a solvent is filled in the trench 11, and the fluent material 12a is subsequently burned to produce the insulator 12 which includes ceramics, for example, barium titanate. Therefore, degradation of the coverage in the trench 11 can be prevented, even when the depth of the trench 11 is longer. Consequently, the productivity of the semiconductor device 1 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
providing trenches in an end terminal area of a substrate, the end terminal area surrounding an element area of the a substrate, the trenches surrounding the element area;
filling a fluent material mixed with carbonate, oxide and solvent in the each of the trenches;
burning the fluent material in the trench to embed an insulator in the trench; and
providing an element unit in the element area.

2. The method of claim 1, wherein
The carbonate is composed of barium carbonate and the oxide is composed of titanium dioxide.

3. The method of claim 1, wherein the solvent is composed of water or alcohol.

4. The method of claim 1, wherein
the insulator includes barium titanate.

5. The method of claim 1, wherein
the providing of the element unit in the element area is performed after the burning of the fluent material.

6. The method of claim 1, wherein
the fluent material is filled in the trench by dispensing technique or spin coating technique.

7. The method of claim 1, further comprising:
removing the insulator remained on the substrate, after the burning of the fluent material.

8. A method of manufacturing a semiconductor device, comprising:
providing trenches in an end terminal area of a substrate, the end terminal area surrounding an element area of the substrate, the trenches surrounding the element area;
filling a fluent material mixed with a powder raw material which includes carbonate and oxide, and solvent in the each of the trenches;
burning the fluent material in the trench to embed an insulator in the trench; and
providing an element unit in the element area.

9. The method of claim 8, wherein
The carbonate is composed of barium carbonate and the oxide is composed of titanium dioxide.

10. The method of claim 8, wherein the solvent is composed of water or alcohol.

11. The method of claim 8, wherein
the insulator includes barium titanate.

12. The method of claim 8, wherein
the providing of the element unit in the element area is performed after the burning of the fluent material.

13. The method of claim 8, wherein
the fluent material is filled in the trench by dispensing technique or spin coating technique.

14. The method of claim 8, further comprising:
removing the insulator remained on the substrate, after the burning of the fluent material.

15. A, semiconductor device, comprising:
an element area which includes an element unit on a substrate;
an end terminal provided at a periphery of the element area;
trenches included in the end terminal area, the trenches surrounding the element area; and
an insulator including barium titanate, the insulator being embedded in each of the trenches.

16. The semiconductor device of claim 15, wherein
the insulator is provided by burning a fluent material mixed with carbonate, oxide and solvent.

17. The semiconductor device of claim 16, wherein
the carbonate is composed of barium carbonate and the oxide is composed of titanium dioxide.

18. The semiconductor device of claim 15, wherein
the insulator is provided by burning a fluent material mixed with a powder raw material which includes carbonate and oxide, and solvent.

19. The semiconductor device of claim 18, wherein
the carbonate is composed of barium carbonate and the oxide is composed of titanium dioxide.
